(19) United States
(12) Patent Application Publication
(10) Pub. No.: US 2008/0253298 A1
(43) Pub. Date: Oct. 16, 2008

(54) Method and System for Managing Routes in a Wireless Network of Nodes

(76) Inventors: Ghulam M. Bhatti, Mansfield, MA (US); Octav Chipara, Richmond Heights, MO (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 11/734,916

(22) Filed: Apr. 13, 2007

(51) Int. Cl. G01R 31/08

(52) U.S. Cl. 370/252

(57) ABSTRACT

A method for manages routes in a wireless network of nodes by determining a distances between each pair of nodes in a set of nodes of a wireless network. The distances are maintained in a memory of a particular node of the wireless network as a distance map in a form of a wavelet, and routing a packet between the nodes is according to the distances stored as the wavelet.

### FIELD OF THE INVENTION

This invention is related generally to routing in wireless networks, and more particularly to routing packets in ad hoc and sensor networks.

### BACKGROUND OF THE INVENTION

Routing in Wireless Networks

Routing is a used to manage an efficient operation of nodes in a wireless network. For example, routing can consider a number of constraints, e.g., minimizing energy consumption, maximizing a network life-time, maximizing a likelihood of successful delivery of packets, or minimizing communication delays.

Routing is usually regarded as an optimization problem in which an optimal route (shortest distance, for example) between nodes is determined according to a constraint of interest. Fundamental for solving this problem is the ability to approximate the optimal routes among nodes efficiently. In accomplishing this, network protocol designers are constrained by resource limitations of the nodes, e.g., available memory, processing power, and communication bandwidth.

The problem of approximating distances, efficiently and cost effectively to improve the performance of a distributed wireless network is not new. For example, in peer-to-peer network, the approximate distances between nodes can be expressed in a virtual multidimensional space, where each node is assigned a set of virtual coordinates, L. Tang and M. Crovella, “Virtual landmarks for the internet,” IMC '0.3: Proceedings of the 3rd ACM SIGCOMM conference on Internet measurement, 2003, pp. 143-152, and B. Wong, A. Slivkins, and E. G. Sirer, “Meridian: a lightweight network location service without virtual coordinates,” SIGCOMM '05: Proceedings of the 2005 conference on Applications, technologies, architectures, and protocols for computer communications, 2005, pp. 85-96. An advantage of that method is a compact representation of distance information. It suffices to know the coordinates of two nodes to determine their approximate distance.

Similarly, methods to assign virtual coordinates that approximate a hop-count distance between nodes has been described in the context of facilitating routing in ad hoc and sensor networks, A. Rao, C. Papadimitriou, S. Shenker, and I. Stoiea, “Geographic routing without location information,” MobiCom '03: Proceedings of the 9th annual international conference on Mobile computing and networking, 2003, pp. 96-108, and T. Moscibroda, R. O'Dell, M. Wattenhofer, and R. Wattenhofer, “Virtual coordinates for ad hoc and sensor networks,” DIALM-POMC '04: Proceedings of the 2004 joint workshop on Foundations of mobile computing, 2004, pp. 8-16.

Another method can use graph embedding, which maps the distances of a graph into a geometric space. The goal is to find mappings that have small distortions in the distances between nodes, N. Linial, E. London, and Y. Rabinovich, “The geometry of graphs and some of its algorithmic applications,” Combinatorica, vol. 15, pp. 215-245, 1995, and J. Newsome and D. Song, “Gem: graph embedding for routing and datacentric storage in sensor networks without geographic information,” SenSys '03: Proceedings of the 1st international conference on Embedded networked sensor systems, 2003, pp. 76-88. Newsome and all use a virtual polar coordinate system.

There are a number of problems with conventional methods. First, most conventional methods are limited to a particular constraint of interest, such as delay or hop-count, instead of a general solution. Second, many conventional method are based on simple distributed heuristics and as such the error in their estimates can be large. Third, conventional methods do not evaluate the overhead involved in constructing coordinate systems.

Wavelet Representations

Wavelets can be used to represent and store values in a space efficient manner. Wavelets have been used extensively in signal and image processing. Wavelets have also been used in query processing and multi-resolution storage, R. S. Wagner, R. G. Baraniuk, S. Du, D. B. Johnson, and A. Cohen, “An architecture for distributed wavelet analysis and processing in sensor networks,” IPSN '06; Proceedings of the fifth international conference on Information processing in sensor networks, 2006, pp. 243-250, and D. Ganesan, B. Greenstein, D. Estrin, J. Heidemann, and R. Govindan, “Multiresolution storage and search in sensor networks,” Trans. Storage, vol. 1, no. 3, pp. 277-315, 2005. Wavelets have also been used in lossy compression by keeping only a small subset of the coefficients obtained during the wavelet decomposition.

Determining which subset of coefficients to retain is a problem. To solve this problem, probabilistic and deterministic methods have been described to provide error guarantees and dynamic maintenance, M. Garofalakis and A. Kumar, “Wavelet synopses for general error metrics,” ACM Trans. Database Syst., vol. 30, no. 4, pp. 888-928, 2005, M. Garofalakis and P. B. Gibbons, “Wavelet synopses with error guarantees,” SIGMOD '02: Proceedings of the 2002 ACM SIGMOD international conference on Management of data, 2002, pp. 476-487, and Y. Matias, J. S. Vitter, and M. Wang, “Dynamic maintenance of wavelet-based histograms,” The VLDB Journal, 2000, pp. 101-110, both incorporated herein by reference.

Wavelets have not been used for optimizing routes in wireless networks.

### SUMMARY OF THE INVENTION

The embodiments of the invention provide a method and system for managing routes between nodes in a wireless communication network. Specifically, distances between nodes are determined. Then, the distances are stored in a set: of distance maps as wavelets that are approximate, and defined by low and high bounds of the distances.

The distance maps can be used to manage the routing in the network. In one application, the distances are used to improve upon existing shortest hop count routing method, e.g. routes that use ad hoc on demand distance vectors (AODV). In another group communication application, the maps are used to construct routing trees and to support data collection and dissemination.

The embodiments of the method provide error guarantees about each distance stored in the maps. The wavelet are be updated as the distances change. This problem is not trivial because the update operation can affect the error bounds of the distances. Due to the resource constraints of wireless sensor nodes, the method for updating the wavelets uses a minimal amount of memory, and is computationally simple.

### BRIEF DESCRIPTION OF THE DRAWINGS

FIG. 1 is a diagram of a wireless network of nodes according to an embodiment of the invention;

FIG. 2 is a method for managing routes in the network of FIG. 1 according to an embodiment of the invention;

FIG. 3 is a diagram of a binary error tree of a wavelet according to an embodiment of the invention; and

FIG. 4 is a block diagram of pseudo code for a procedure to determine error bounds according to an embodiment of the invention.

### DETAILED DESCRIPTION OF THE PREFERRED EMBODIMENTS

Network

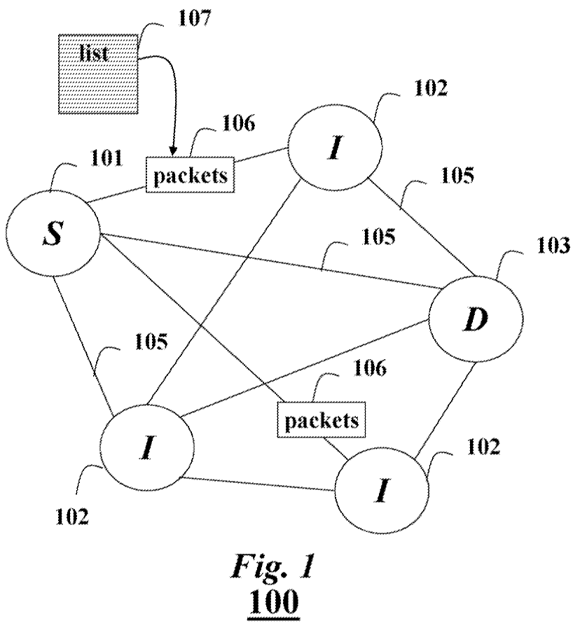

FIG. 1 shows a network of nodes of a wireless network 100 according to an embodiment of our invention. The network can include a source node S 101, intermediate nodes I 102, and a destination node D 103. Packets 106 are communicated from the source to the destination node, perhaps via the intermediate nods, along routes. The pay load in a particular packet 106 is p.

Therefore, the packets pay load includes a list of a subset of nodes that can form a route. The list 107 is described in greater detail below.

The lines 105 between the nodes indicate possible routes for communicating a packet 106. In a preferred embodiment, the network is an ad hoc network or a sensor network. As a consequence, the nodes 101-103 have limited available resource, such as memory, power, processing capability, memory and bandwidth.

Distance Maps

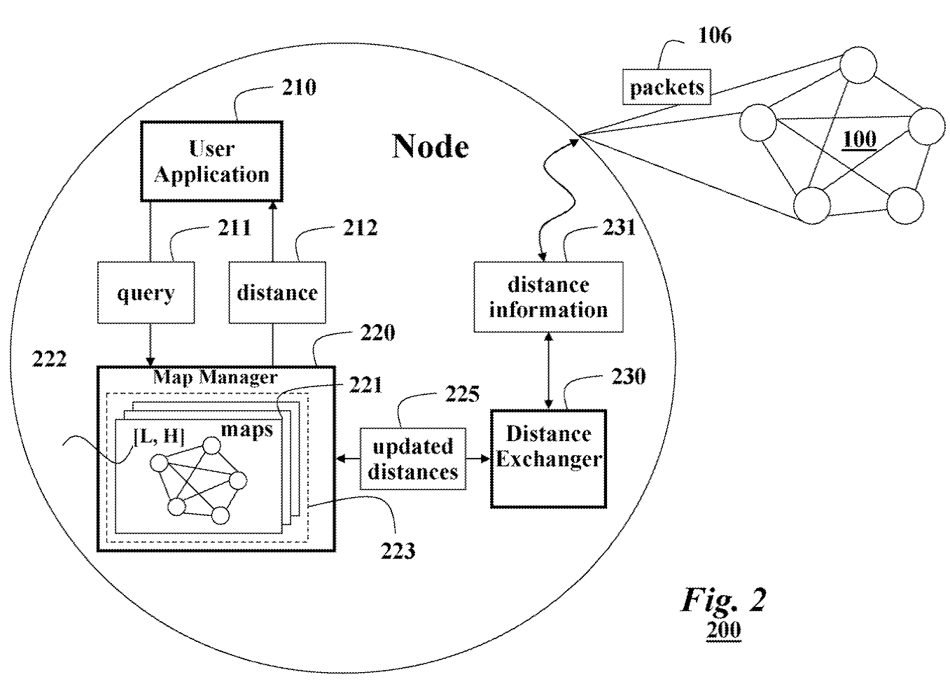

As shown in FIG. 2, the embodiments of our invention provide a method and system 200 for constructing and maintaining a set of distance maps 221 for the nodes 101-103 in the wireless network 100. A distance map stores the distances between pairs of nodes.

The term ‘distance’ is defined generally here. Distance can be the actual geographical distance between nodes, the number of hops, the amount of energy required to communicate with the other node, the signal strength or link quality indicator (LQI), average delay, buffering capacity, bandwidth, and so forth. Any of these metrics can constrain the routing. Therefore, a separate distance map can be maintained for each distance metric, or a combination of metrics.

Typically, the set of pairs is less than all possible pairs. As defined herein, a set can include one or more members. The reasons why the set of nodes for which distances are determined is a subset of all possible nodes are as follows.

We are considering networks of hundreds or perhaps thousands of low-cost, low power nodes. Distances for all possible pairs in such a network would be impractical to store because the nodes have limited resources managing. Thus, routing in the network is difficult. First, measuring distances between the nodes in a metric space can be costly. That is, measuring the distances between all pairs of nodes, using a hop count as a metric, requires the construction of a shortest route between many pairs of nodes. We reduce the cost by providing hints regarding distances of interest. In addition, determining the exact distance between nodes is often unnecessary, and approximate distance estimate can be sufficient in many situations.

Second, even if evaluating the distances between all node pairs is performed, nodes in a large wireless sensor network may not necessarily be able to store all of the distances due to limited memory. Therefore, the size of the set of distance maps needs to be minimized.

Third, the exchange of information between nodes is constrained by the small size of the packets 106, which is a characteristic of most wireless ad hoc and sensor networks.

Fourth, the distances between the nodes can change over time, particularly in an ad hoc network where nodes enter and leave in an unpredictable manner, and in sensor network where the nodes might be mobile. In addition, the distances may changes due to node failures, changes in the wireless environment or topology. Therefore, the method needs to be adaptive and have a low communication overhead.

As shown in FIG. 2, our method and system 200 includes a distance map manager 220, and a distance exchanger 230. The method operates with the nodes of the network 100. The map manager 220 receives a query 211 from a user application 210 requesting the distance between a particular pair of nodes. The request can also specify an attribute of the nodes, and which distance metric to use. The map manager responds a distance 212. The distance is specified in terms of a low and high bound [L, H] 222 of the metric. The map manger stores, organizes and maintains the set of distance maps 221 in the memory 223 of the nodes.

The map manger represents each distance map as a wavelet, which is constructed by using a Haar decomposition. We keep the storage requirements to a minimum by storing and maintaining only a small subset of coefficients of the wavelet. The subset of coefficients is selected in such a way as to minimize errors.

To determine low and high bounds 222 of the distances 212, as required for our approximate distance map service (ADMS), we track errors introduced while deleting coefficients. This is accomplished by constructing a small group of clusters based on deleted wavelet coefficients. We keep track of the errors resulting from deleting a coefficient by storing a cluster ID in which the cluster was classified. The map manager is also used to determine the low and high bounds [L, H] 222 on the distances.

The distance exchanger is responsible for exchanging distance information 231 with other nodes in the network 100. This is accomplished by carefully determining the information 231 that is inserted in each packet to minimize communication overhead, while ensuring the information is up to date.

Approximate Distance Map Service (ADMS)

Our ADMS constructs the set of distance maps 221 for a user-specified metric space. The main goal of the ADMS is to provide the distance 212 between two nodes in response to the query 211. The distance is provided as the range [L, H], i.e., the low and high bounds 222.

For each map 221, the user application specifies a metric space, and a size for the memory 223 allocated for each map (M_{size}) 221 in the set. Formally, the metric space is defined as a two-tuple (X, d), where X is a user specified subset of the nodes to include in each map, and the distance metric is (d; V×V [symbol] [symbol] ), which satisfies the following properties:

d(A, B)≧0, (1)

d(A, B)=0, if and only if A=B, (2)

d(A, B)=d(B, A), and (3)

d(A, B)≦d(A, C)+d(C, B), i.e., the triangle inequality, (4)

for nodes A, B, and C.

As stated above, the definition of the metric d can vary. For example, the distance d(A, B) can be the route that requires the smallest number of transmissions and retransmissions between nodes A and B, or the number of hops. Such routes are of interest for applications that require energy efficient routes with small delays. More complex metrics, such as the power aware routing can be supported, see S. Singh, M. Woo, and C. S. Raghavendra, “Power-aware routing in mobile ad hoc networks,” Mobile Computing and Networking, 1998, pp. 181-390, incorporated herein by reference.

The user application 210 can specify the nodes that are included in the each map 221. The user application can also specify the nodes to which distances are maintained based on their distance values, or other node attributes. For example, a node N maintains a distance map for a set of nodes

{M|d(N, M)<d′},

i.e., pairs of nodes with distances less then d′.

Similarly, the user application can specify to only include nodes of having particular attributes, e.g., the attribute specifies node type, such temperature sensors. Such a map is useful for setting up group communication among sensor nodes with common attributes.

Notations

The actual distance between a pair of nodes A and B is \hat{d} (AB). The estimated distance in map M of node N is d_{N}^{M} (AB). When the map context is clear, we do not use the superscript M. The relative error in the distance in the map M maintained by node N is

$${ɛ}_{N}^{M} ( AB ) = \frac{{d}_{N}^{M} ( AB ) - \hat{d} ( AB )}{\hat{d} ( AB )} , \qquad ( 5 )$$

in which ε_{N}^{M} is the maximum relative error in the map M at node N, while ε^{M} represents the maximum relative error in map M.

Applications for ADMS

ADMS applications can include peer-to-peer routing, and group communication.

Generalized Peer-To-Peer Routing

We describe a routing protocol that uses ADMS to construct energy efficient routes and with a low overhead both for setup and maintenance. Our insight is that ADMS can be used to determine a next forwarding node based on the distance maps 221. Consider the case when routing a packet from the source node S 101 to the destination node D 103, and the packet 106 has been received by some intermediate node I 102. This node determines a suitable next node towards the destination node. Some of the neighboring nodes of node N may be closer to the destination node D than other nodes.

A node M is a good candidate for being the next node if the node reduces the distance towards the destination node D according to a considered metric, i.e., d(N D)>d(M D). To determine which nodes are good candidates for the next hop, the node N can use ADMS to find the distances d(M D) from each of its neighboring nodes to the destination node D.

However, because node M is closer to the destination node D, node M may have a more accurate estimate of the distance d(M D). To exploit this, we use the following approach. When a node N receives a packet to be forwarded to the destination node D, the node N transmits the packet containing the address of destination node D in the packet header. Upon receiving the packet, a neighboring node M of node N queries 211 the ADMS to provide an error-bounded estimate of the distance d(M D) to the destination node.

Based on the reply 212, the node M can determine whether the packet can progress towards destination node. Node M can reach one of the following conclusions:
a. the packet makes progress to the destination;
b. the packet does not make progress to the destination; or
c. the node cannot determine whether the packet makes progress toward the destination node.

If node M cannot progress the packet toward the destination, then the node m does not forward the packet. Otherwise, the node M forwards the packet as follows. If the node M knows that the packet can make progress toward the destination node, then the node M selects a back-off in the interval inversely proportional to the progress the packet makes towards destination. After node M transmits the packet, the node M sends an acknowledgement packet back to node N indicating that the packet has been successfully forwarded.

If node N does not receive an acknowledgement packet from any of its neighbor nodes, the node N assumes that none of its neighboring nodes actually were able to progress the packet towards destination. This situation may be indicative of a local problem in the routing, which needs to be surpassed by other means.

In such a case, our protocol allows the packet to be transmitted by using a local broadcast with a small broadcast radius, e.g., no more than three hops. This ensures that the packet does not get stuck in a cluster of nodes that has no good forwarding route to the destination.

Apart from broadcasting the packet, the node N selects not to accept packets for that particular destination node D in future for a pre-defined time interval. This enables the node N to participate in forwarding packets towards the destination node D some time in the future, perhaps, after network condition have changed.

Another possible problem with routing based on coordinates is the formation of cycles in the route towards the destination node D. In order to avoid or break such a cycle, we allow the recording of addresses of forwarding nodes along the route towards destination node in the packet. However, we do not need to record the addresses of all nodes on the route. Rather, only a small subset of most recent forwarding nodes is recorded. That suffices because the cycles tend to involve only closely located nodes, and the number of such nodes is usually not large. Therefore, the overhead cost of storing the addresses of relatively small number of nodes in a packet is not excessively high.

Thus, each node, while transmitting a packet, adds its address at the top of the list 107, and deletes the address of the oldest forwarding node from the bottom of the list. A node N accepts packets for transmission only if its address is not included in the list of forwarding nodes.

The above protocol has several features. The protocol can be used with any user-defined routing metric. The protocol finds routes between any communication peers. Furthermore, as the distance maps are updated, the protocol can select new routes.

Group Communication

A similar protocol can be used to setup multi-cast trees to support data dissemination, collection, and aggregation. Such operations are very common in sensor networks, S. R. Madden, M. J. Franklin, J. M. Hellerstein, and W. Hong, “Tinydb: an acquisitional query processing system for sensor networks,” ACM Trans. Database Syst., vol. 30, no. 1, pp. 122-173, 2005, and S. Madden, M. J. Franklin, J. M. Hellerstein, and W. Hong,” OSDI, Volume 36, pp. 131-146, 2002, incorporated herein by reference.

A group is formed among nodes with common attributes. One of these nodes is designated as the group leader. Communication with in the group supports two primitive operations: disseminating data from the group leader to the group members, and collecting data from the group members at the group leader. The group leader is commonly a base station. We assume that the group leader discovers the IDs of the group members through a conventional discovery mechanism.

ADMS construct the multicast tree as follows. The group leader broadcasts a packet that contains the IDs of all members of the group. Each neighboring node N determines if the node N can progress a packet to at least one of the group members. If the node N does, then the node N replies with an acknowledgement packet that includes the IDs of only those group members M, such that node N can progress the packet toward node M. Thus, the replying node becomes part of the multicast tree, even if it is not a group member.

After inspecting the received replies, a node can easily determine if none of its neighbor nodes can progress the packet towards any of the group members. In such a case, local flooding, similar to the case in peer-to-peer routing, can be adapted to discover a route towards an isolated group member. Flooding is a technique where each node that receives a packet, broadcasts the packet to neighboring node, such that the likelihood of the packet making progress is increased. Note that the flooding is limited only to those nodes that make progress. When such a node is located, the route to the node is added to the multi-cast tree. The process is repeated to form the multi-cast tree.

Protocol Design

As shown in FIG. 2, the ADMS protocol includes the map manager 220 and the distance exchanger 230. The map manger 220 manages the limited storage space in the node, and responds to queries 211 from the user application 210. The response to a query is the range 222 of the distance between two nodes. The distance exchanger provides distance information between other nodes of the network 100 to construct the desired maps 221. The user application 210 can use ADMS in two ways. It can query the map manager to determine a distance to a node. In addition, the user application can be notified about distance changes. This way, the user only needs to query for a new distance when the distance changes.

Map Manager

The map manager stores the distance information as wavelets. Wavelets are a tool designed to approximate a sequence of input values at different levels of detail in a space efficient manner. To the best of our knowledge wavelets have not been used for storing network routing information. We construct the wavelets using a Haar decomposition. The Haar decomposition considers a sequences of coefficients values (v₀, v₁, . . . , vₙ), and determines at set of n coefficients, which can be used to reconstruct the initial values without errors.

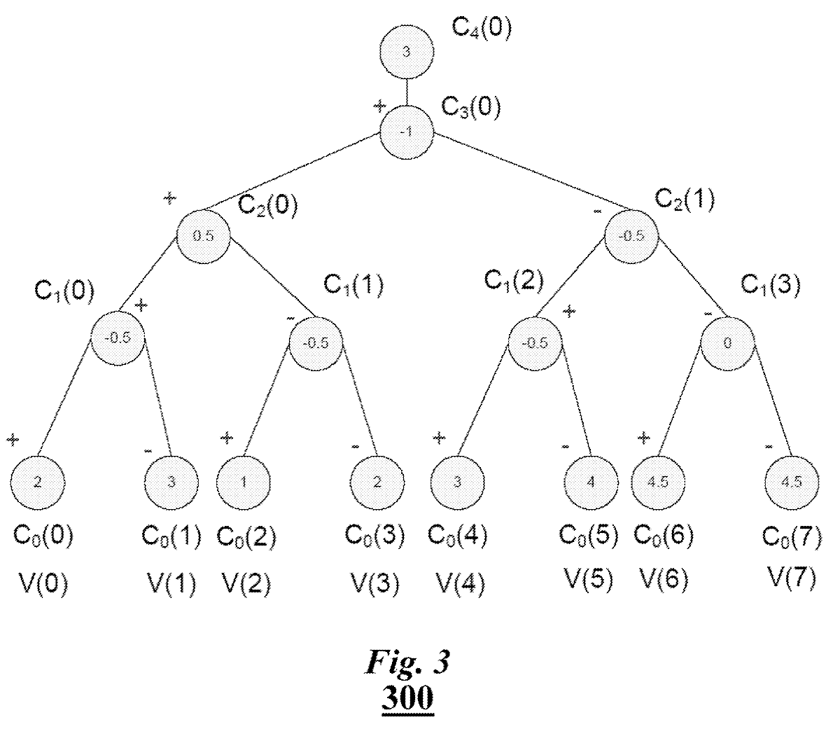

As shown in FIG. 3, the Haar decomposition constructs a binary error tree 300, which has the input sequence as (bottom level) leaves and the coefficients as internal nodes. We denote a coefficient by cₗ(i). The subscript l indicates the level in the tree with the values residing. A height of the tree is h, and the index of the coefficient on level l is i.

The Haar decomposition constructs the tree 300 in a bottom up fashion, from the leaves to the root (C₄(0). As shown in FIG. 3, the bottom level nodes are the distances {2, 3, 1, 2, 3, 4, 4.5, 4.5} between a particular node and eight other nodes. The level 1 nodes are determined from the level 0 leaf nodes as follows. First, we determine an average a₁(0) of values v₀ and v₁. Next, we determine the values of c₁0) to a₁(0)−v₁=(v₀−v₁)/2. That is, the next higher parent node is a difference between an average of the two child nodes and the right most child node.

The procedure is repeated to fill in the values of the nodes at level 1. Recursively, we construct the nodes of the next level l+1 from the values determined at level 1 by determining the coefficient cₗ₊₁(i) according to the following equation;

cₗ₊₁(i)=(cₗ(2i)−cₗ(2i+1))/2, for all i greater than zero, (6)

and so forth until the root of the tree is reached. At that point, the leaf nodes can be discarded. Thus, the wavelet is a form of compression, since the discarded leaf nodes may have a large range of values and consume a large amount of storage, while the retained intermediate nodes are only relatively small (delta) values consuming much less memory.

The initial value vᵢ can be reconstructed from the wavelet coefficients in the tree 300 according to the following equation;

$${υ}_{i} = {\sum }_{{c}_{l} ( j ) ε path ( {υ}_{i} )} sign ( {υ}_{i} , {c}_{l} ( j ) ) \cdot {c}_{l} ( j ) , \qquad ( 7 )$$

where sign is 1 when the value vᵢ is in the left child subtree of cₗ(j), or for cₕ(0).

This alone does not reduce the storage memory requirements by using the Haar decomposition. However, many of the coefficients of the Haar decomposition are often negligibly small values, i.e., close to zero. These coefficients can be ignored without introducing large errors. Such a wavelet from which some coefficients have been deleted is called a compressed wavelet. While wavelet summaries have been extensively used by database and image processing applications, the application of wavelets to maintain approximate distance maps in a wireless network is believed to be novel.

The above construction has the following constraints. Error bounds about each distance stored in the map need to be provided. The operations performed on the wavelet are insertions, updates, and deletions. The operations are performed on the compressed wavelet because the actual values of the distances are deleted after their insertion in the distance map 221. This constraint is difficult because insertions and updates can affect the error bounds as described below. The execution of wavelet operations should use a small amount of the memory 223. Furthermore, the wavelet operations should be completed in polynomial time.

While work has been done on solving each of the above constraints individually, the combination of the above constraints makes our construction novel, because none of the convention wavelet decomposition procedures are unusable for this purpose.

In order to make the error introduced by the compression of the wavelet bounded, we describe how the error is affected by insertions and updates. Several cost functions be used to evaluate the quality of a wavelet compression. In the following, we concentrate on a maximum absolute error. However, our method can be extended for minimizing a relative error or a sum of squared differences between the value of actual error and its approximation. To gain some understanding on how the compression affects the relative error, we consider how the low and high bounds on a distance v(j) can be determined based on the wavelet coefficients.

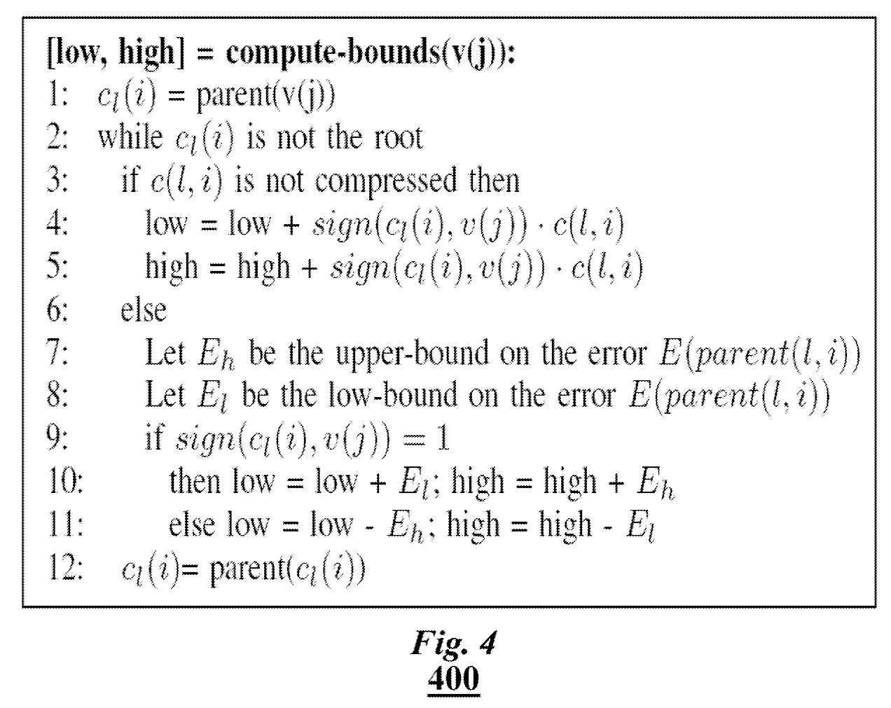

FIG. 4 shows a procedure 400 for determining the bounds. The procedure 400 takes the index of v(j) as input, and produces the bounds [low, high] on the distance as its output. The procedure first considers the coefficient cₗ(i), which is the parent of value v(j). If cₗ(i) is not the compressed root, then its value can be found in the wavelet.

Based on the value cₗ(i), and the value of sign(cl(i), v(j), we update the low and high bounds as shown in lines 4-5 of FIG. 4. If the coefficient v(j) is compressed, then its value is not maintained in the wavelet. However, to be able to bound the error, we maintain some additional information about the coefficients that have been deleted. An effective approach is to track the minimum (Eₗ) and maximum (Eₕ) error bound of the compressed wavelets. With this additional information, the low and high bounds of the distance can be updated as shown in lines 9-12. Next, the procedure considers iteratively the ancestors of cₗ(i), until the root of the error tree is reached.

The procedure 400 indicates that in order to have tight bound on a value, we determine the wavelet coefficients that can be deleted. We track the distribution of the deleted coefficients in a space-efficient way. For this, we use k-means clustering. The user application specifies a small number of error clusters that can be used for this purpose.

For each cluster, we maintain the average of all coefficients belonging to the cluster, and the low and high bounds on the values that belong to the same cluster. When a coefficient is determined as to be deleted, the coefficient is inserted in one of the error clusters.

The k clusters are initialized based on the first k values. Based on the value of the deleted coefficient, we have two options. First, the value can be inserted into the cluster whose lower/upper bounds are least affected by the insertion of the coefficient, or a new cluster can be generated.

Clusters can be merged in order to keep the total number of clusters within a reasonable limit. So, while inserting a coefficient into a cluster, we can use an existing cluster, or generate a new cluster specifically for the coefficient being deleted.

We also check a possibility of merging clusters. This happens when distance d(cl(i), ecₖ), where ecₖ is a mean of the cluster in which cₗ(i), is inserted is higher than ail distances between the cluster means. The procedure determines the cluster index in which the value is inserted. If a new cluster is inserted, then the wavelet is update to indicate this change.

The insertion or update operations affect both the wavelet coefficients and the error bounds. In the following, we describe a procedure for updating the wavelet and error information of a compressed wavelet. The update operation is used to insert new values in the wavelet.

We make several observations.

Lemma 1: If we switch coefficients cₗ(i)=−cₗ(i), and invert the left and right subtrees, then we do not introduce any error.

Lemma 2: If coefficient cₗ(i) is deleted, then the absolute error of values vⱼ ∈ leaves(l, i) is ε(vⱼ)=sign(vⱼ, cₗ(i))·cₗ(i). This does not affect the values vⱼ ∉ leaves(l, i).

Distance Exchange Protocol

One of the challenges of our method is to efficiently gather the distance information 231 from nodes with low error. The key to achieving this is to maximize the amount of information a node gains from a packet the node receives.

In one embodiment, each node periodically broadcasts a packet containing its source ID and hop count. In this solution, the receiving node increments the hop count in the packet and retransmits the packet. However, this has a high overhead. Also, note that the amount of information gained from each packet is limited because a packet contains a single distance measurement.

In another embodiment, each node includes additional information in each packet. Recall, each node maintains a map based on the accumulated distance information. However, the network 100 uses small packets. Therefore, the overhead introduced by transmitting the entire map can be high.

Another embodiment compresses the distance map until the map fits in a single packet. Unfortunately, this comes at the cost of decreased accuracy due to the limited packet size. This can lead to deterioration in the quality of the map because a node can receive low errors distance measurements.

A practical alternative transmits only a subset of the information in each broadcast packet. A down-sampling technique can be used to determine the distances that are included in the transmitted packet. As such, a node selects to insert in the payload of the packet the high bound on the distance d(A B) with probability pᵢₙₛₑᵣₜ(AB)=1/(number of distances). Over time, the node broadcasts all its distances enabling the distance exchangers of other nodes to obtain the desired distances.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method for managing routes in a wireless network of nodes, comprising;
determining a distances between each pair of nodes in a set of nodes of a wireless network;
maintaining the distances in a memory of a particular node of the wireless network as a distance map in a form of a wavelet; and
routing a packet between the set of nodes according to the distances stored as the wavelet.

2. The method of claim 1, further comprising;
specifying each distance as a low bound and a high bound on the distance.

3. The method of claim 1, in which the set of nodes is a subset of all possible nodes in the network.

4. The method of claim 1, in which the particular nodes stores a plurality of distance maps for a plurality of set of nodes as a plurality of wavelets, there being one wavelet for each distance map.

5. The method of claim 1, in which the distance is a metric selected from a group comprising a geographical distance between the pair of nodes, a number of hops between the pair of nodes, an amount of energy required to communicate between the pair of nodes, a signal strength between the pair of nodes, an average delay between the pair of nodes, a buffering capacity in the pair of nodes, a bandwidth between the pair of nodes, and combinations thereof.

6. The method of claim 1, in which a particular distance is provided to a user application in response to a query.

7. The method of claim 1, in which the distance map is constructed using a Haar decomposition, and further comprising:
maintaining a subset of coefficients of the decomposed wavelet in the memory.

8. The method of claim 1, in which a relative error in a distance d(AB) in a particular distance map M maintained by the particular node N is
$${ɛ}_{N}^{M} ( AB ) = \frac{{d}_{N}^{M} ( AB ) - \hat{d} ( AB )}{\hat{d} ( AB )}$$
for a pair of nodes A and B, and d is an estimated distance and \hat{d} is an estimated distance.

9. The method of claim 1, further comprising:
determining a next forwarding node according to the distance map by reducing a distance the packet needs to travel to a destination node.

10. The method of claim 7, in which the Haar decomposition produces a binary tree of the subset of coefficients.

11. A system for managing routes in a wireless network of nodes, comprising:
a set of nodes of a wireless network, in which each pair of nodes has an associated distances between the pair of nodes;
means for maintaining the distances in a memory of a particular node of the wireless network as a distance map in a form of a wavelet; and
means for routing a packet between the set of nodes according to the distances stored as the wavelet.
